(19) United States
(12) Patent Application Publication
(10) Pub. No.: US 2013/0022764 A1
(43) Pub. Date: Jan. 24, 2013

(54) HOUSING WITH PATTERNS AND METHOD FOR FORMING PATTERNS ON THE HOUSING

(71) Applicants: CHING-YU CHOU, Tu-Cheng (TW); CHANG-CHIN WU, Tu-Cheng (TW)

(72) Inventors: CHING-YU CHOU, Tu-Cheng (TW); CHANG-CHIN WU, Tu-Cheng (TW)

(73) Assignee: HON HAI PRECISION INDUSTRY CO., LTD., Tu-Cheng (TW)

(21) Appl. No.: 13/290,133

(22) Filed: Nov. 7, 2011

(30) Foreign Application Priority Data
Jul. 19, 2011 (TW) 100125399

(51) Int. Cl. G03F 7/24; B32B 3/10; B32B 1/02

(52) U.S. Cl. 428/34.1; 430/325

(57) ABSTRACT

A method for forming patterns on a curved surface of an article includes of the following steps: a photo-resist layer is coated on the curved surface, in which a material of the photo-resist layer is, for example, a negative photo-resist; a photo-mask is provided, and the photo-mask is placed above the curved surface, in which at least one light hole is defined in the photo-mask; in addition, a shape of the at least one light hole corresponds to a shape of the pattern; a light source is provided, and the photo-resist layer is exposed; and the photo-resist layer is developed after being exposed to form the pattern on the curved surface.

### BACKGROUND

1. Technical Field

The present disclosure generally relates to a method of forming patterns and housings with patterns formed thereon, and particularly, to a method of forming patterns on curved surface of the housing, and housings with patterns formed on a curved surface thereon.

2. Description of Related Art

To form patterns on a curved surface of various articles, silk screen printing or ink jet printing are usually employed. However, such patterns can only be formed on an outer convex surface by silk screen printing, and if an article structure is too complicated, the patterns cannot be formed. For ink jet printing, because the distances between the to-be-printed points on the curved surface and a printing head of a printer are not the same, the ink jetted on the curved surface is not uniform and thus the resolution of the pattern produced is relatively low, and the pattern may be distorted. To improve the pattern quality, the movement path of the printing head can be controlled according to a profile of the curved surface, such that the distances between the to-be-printed points and the printing head are similar enough. However, a printing apparatus as mentioned above has a relatively complicated structure, and relatively high cost.

Therefore, there is room for improvement within the art.

### BRIEF DESCRIPTION OF THE DRAWINGS

FIG. 1 is a schematic, side cross-sectional view of an exposure process of a method of one embodiment.

FIG. 2 is a schematic, side cross-sectional view of a developing process of the method of one embodiment.

FIG. 3 is a schematic, side cross-sectional view of a housing with a pattern formed on the housing by the method of the embodiment.

FIG. 4 is a schematic, top view of the housing of FIG. 3.

FIG. 5 is a flowchart of a method for forming a plurality of patterns on a housing of an illustrated embodiment.

### DETAILED DESCRIPTION

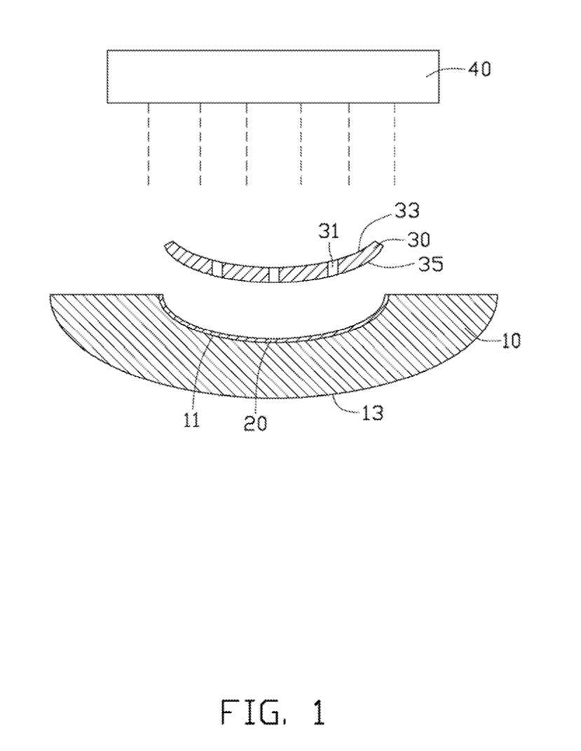

Referring to FIG. 1, an illustrated embodiment of a method for forming a plurality of patterns on a curved surface of an article is shown. In the illustrated embodiment, the method of forming the patterns on a housing 10 is presented. The housing 10 is substantially curved, and includes an inner concave surface 11 and an outer convex surface 13 opposite to the inner concave surface 11. A photo-resist layer 20 is coated on the inner concave surface 11. A material of the photo-resist layer 20 can be a negative photo-resist or a positive photo-resist. In the illustrated embodiment, the housing 10 is made of metal. The housing 10 can be made of glass, ceramic, or plastic, for example.

A photo-mask 30 employed in the method of forming the patterns in the illustrated embodiment is substantially curved. A plurality of light holes 31 are defined in the photo-mask 30. The photo-mask 30 includes an inner concave surface 33 and an outer convex surface 35 opposite to the inner concave surface 33. The outer convex surface 35 is placed adjacent corresponding to the inner concave surface 11 of the housing 10, and a profile of the outer convex surface 35 is substantially the same as that of the inner concave surface 11. In the illustrated embodiment, because the material of the photo-resist layer 20 is the negative photo-resist, a shape of the light holes 31 corresponds to that of a pattern to be formed on the inner concave surface 11. Each light hole 31 is substantially elliptical when viewed in top view.

If the material of the photo-resist layer 20 is a positive photo-resist, a shape of the outer convex surface 35 corresponds to that of the pattern to be formed on the inner concave surface 11. The photo-mask 30 can be planar, and a corresponding relation between the shape of the light holes 31 and that of the pattern should be calculated in that case.

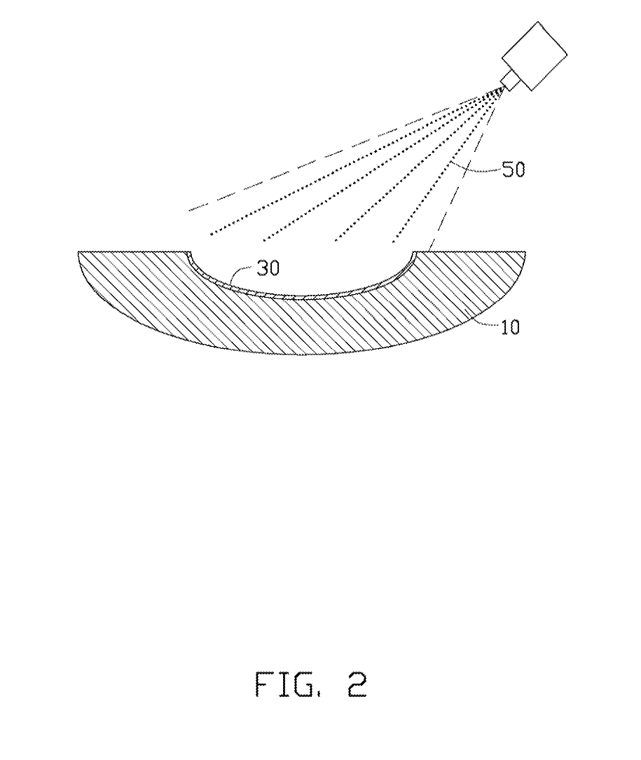

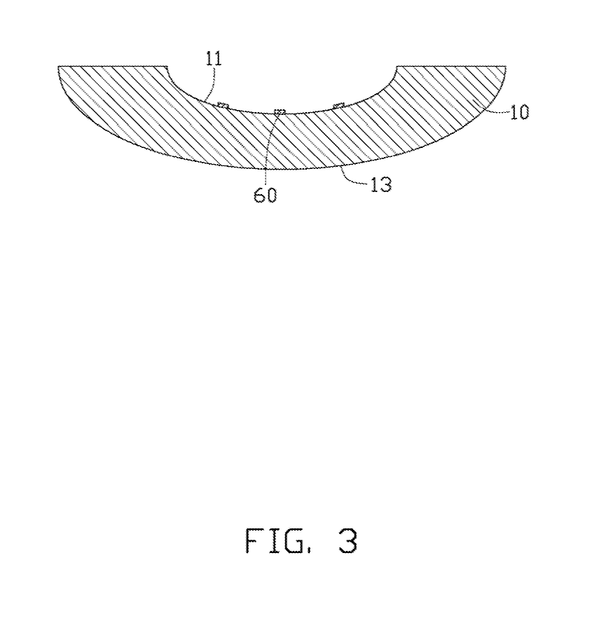

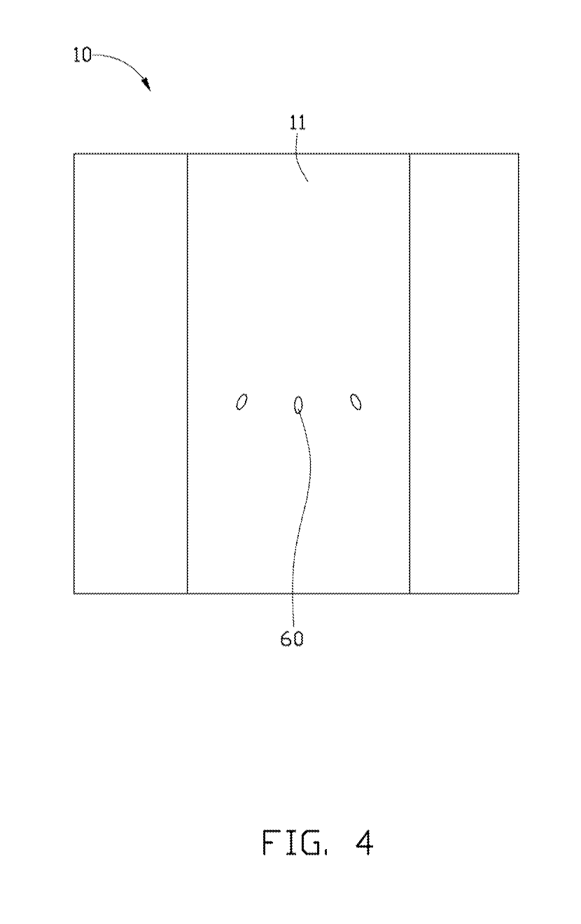

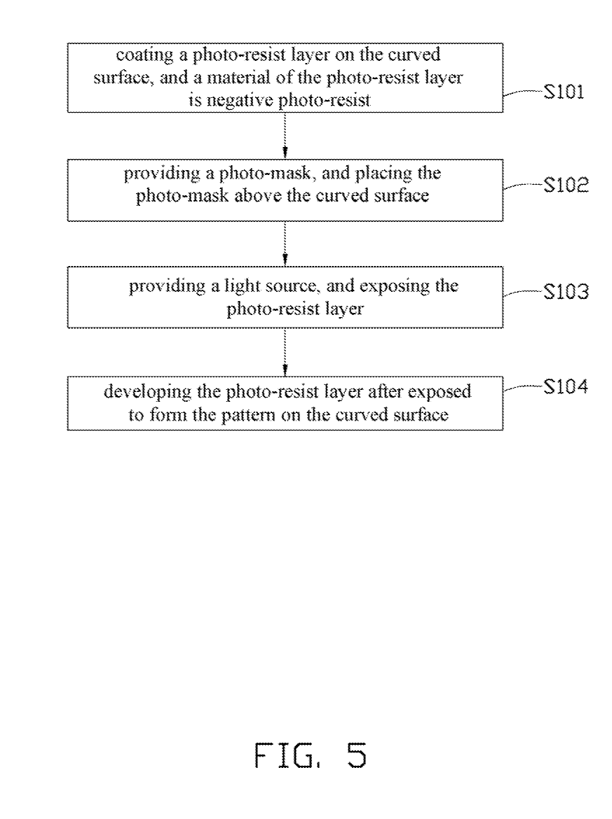

Referring to FIGS. 2 through 5, a method of forming a plurality of patterns of one embodiment includes the following steps.

In a first step S101, a photo-resist layer 20 is coated on an inner concave surface 11 of the housing 10. The photo-resist layer 20 can be coated by an immersion process or a spraying process. In the illustrated embodiment, the photo-resist layer 20 is coated by the spraying process, and a material of the photo-resist layer 20 is a negative photo-resist. The material of the photo-resist layer 20 can be a positive photo-resist.

In a second step S102, a photo-mask 30 is provided, and is placed above the inner concave surface 11 of the housing 10. A plurality of light holes 31 are defined in the photo-mask 30. The photo-mask 30 includes an inner concave surface 33 and an outer convex surface 35 opposite to the inner concave surface 33. The outer convex surface 35 of the photo-mask 35 is placed corresponding to the inner concave surface 11 of the housing 10. In the illustrated embodiment, because the material of the photo-resist layer 20 is the negative photo-resist, and a profile of the outer convex surface 35 is substantially the same as that of the inner concave surface 11, a shape of the light holes 31 corresponds to that of a pattern to be formed on the inner concave surface 11. Each light hole 31 is substantially elliptical when viewed in top view. If the material of the photo-resist layer 20 is a positive photo-resist, a shape of the outer convex surface 35 corresponds to that of the pattern to be formed on the inner concave surface 11.

In a third step S103, a light source 40 is provided, and the photo-resist layer 20 is exposed to the light emitted from the light source 40. The light passes through the light holes 31 toward the photo-resist layer 20 coated on the inner concave surface 11, and thus the photo-resist layer 20 is exposed to light accordingly, and generates a product, which is undissolvable in a developer.

In a fourth step S104, a developer 50 is provided, and the photo-resist layer 20 after being exposed is developed to form a pattern 60 on the inner concave surface 11 of the housing 10. The developer 50 is sprayed onto the photo-resist layer 20, and the unexposed photo-resist is dissolved in the developer 50, and discharged from the housing 10 together with the developer 50.

The method of forming a plurality of patterns can be used to form the patterns on the outer convex surface 13.

A shape of the pattern 60 can be controlled by the shape of the light holes 31, thereby avoiding forming the pattern 60 on the inner concave surface 11 by directly jetting ink, such that a resolution of the pattern 60 is thereby improved, and the apparatus for forming the pattern 60 has a simpler structure and lower cost. In addition, even though the structure of the housing 10 is relatively complicated, the pattern 60 can be easily formed by the method of the embodiment.

It is to be understood, however, that even though numerous characteristics and advantages of the disclosure have been set forth in the foregoing description, together with details of the structure and function of the embodiments, the disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A method for forming a plurality of patterns on a curved surface of an article, comprising the steps of :
coating a photo-resist layer on the curved surface, and a material of the photo-resist layer being a negative photo-resist;
providing a photo-mask, and placing the photo-mask above the curved surface, wherein at least one light hole is defined in the photo-mask, and a shape of the at least one light hole is corresponding to a shape of the pattern;
providing a light source, and exposing the photo-resist layer; and
developing the photo-resist layer after being exposed to form the patterns on the curved surface.

2. The method for forming the patterns on the curved surface of the article of claim 1, wherein the photo-mask comprises a curved surface having a profile that is substantially the same as a profile of the curved surface of the article, the curved surface of the photo-mask is placed corresponding to the curved surface of the article, and a shape of the at least one light hole corresponds to the shape of the pattern.

3. The method for forming the patterns on the curved surface of the article of claim 1, wherein the photo-mask is planar, and a corresponding relation between the shape of the pattern and the shape of at least one light hole is calculated to define the at least one light hole in the photo-mask.

4. The method for forming the patterns on the curved surface of the article of claim 1, wherein a material of the article is selected from a group consisting of metal, plastic, glass, and ceramic.

5. The method for forming the patterns on the curved surface of the article of claim 1, wherein the curved surface is an inner concave surface or an outer convex surface opposite to the inner concave surface.

6. A method for forming a plurality of patterns on a curved surface of an article, comprising the steps of :
coating a photo-resist layer on the curved surface, and a material of the photo-resist layer being a positive photo-resist;
providing a photo-mask, and placing the photo-mask above the curved surface, wherein at least one light hole is defined in the photo-mask, and a shape of the photo-mask corresponds to a shape of the pattern;
providing a light source, and exposing the photo-resist layer; and
developing the photo-resist layer after being exposed to form the patterns on the curved surface.

7. The method for forming the patterns on the curved surface of the article of claim 6, wherein the photo-mask comprises a curved surface having a profile the same as a profile of the curved surface of the article, the curved surface of the photo-mask is placed corresponding to the curved surface of the article, and a shape of the curved surface of the photo-mask corresponds to the shape of the pattern.

8. The method for forming the patterns on the curved surface of the article of claim 6, wherein the photo-mask is planar, and a corresponding relation between the shape of the pattern and the shape of the at least one light hole is calculated to define the at least one light hole in the photo-mask.

9. The method for forming the patterns on the curved surface of the article of claim 6, wherein a material of the article is selected from the group consisting of metal, plastic, glass, and ceramic.

10. The method for forming the patterns on the curved surface of the article of claim 6, wherein the curved surface is an inner concave surface or an outer convex surface opposite to the inner concave surface.

11. A housing with a pattern formed on a curved surface thereof, wherein the pattern is formed by exposing and developing a photo-resist layer coated on the curved surface.

12. The housing with the pattern formed on the curved surface thereof of claim 11, wherein the curved surface is an inner concave surface or an outer convex surface.
